(19) United States
(12) Patent Application Publication
(10) Pub. No.: US 2026/0323860 A1
(43) Pub. Date: Oct. 15, 2026

(54) SERVER DEVICE

(71) Applicants: INVENTEC (PUDONG) TECHNOLOGY CORPORATION, Shanghai (CN); INVENTEC CORPORATION, Taipei City (TW)

(72) Inventor: Chang-Hsin CHIU, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 19/468,113

(22) Filed: Feb. 3, 2026

Related U.S. Application Data
(60) Provisional application No. 63/768,321, filed on Mar. 7, 2025.

(30) Foreign Application Priority Data
May 16, 2025 (CN) 202510633955.9

(51) Int. Cl. H05K 7/14

(52) U.S. Cl. CPC H05K 7/1489

(57) ABSTRACT

A server device includes a casing, a first vertical wall, a second vertical wall, and an expansion module rack. The casing includes a base plate. The first and second vertical walls are fixed to the base plate, and the first and second vertical walls are parallel to each other and spaced apart from each other to define a receiving bay between the first and second vertical walls. The expansion module rack is detachably inserted into the receiving bay and slidable to an assembly position or a pre-assembly position. When the expansion module rack is in the assembly position, the expansion module rack at least partially covers a cable routing space between the expansion module rack and the base plate. When the expansion module rack moves from the assembly position to the pre-assembly position, the expansion module rack exposes the cable routing space.

### CROSS-REFERENCE TO RELATED APPLICATIONS

This non-provisional application claims priority under 35 U.S.C. § 119(a) on Patent Application No(s). 202510633955.9 filed in China, on May 16, 2025 and United States Provisional Application 63/768,321, filed on Mar. 7, 2025, the entire contents of which are hereby incorporated by reference.

### BACKGROUND OF THE INVENTION

### Technical Field of the Invention

This invention relates to a server device, especially to a server device that effectively utilizes internal space thereof while facilitating cable routing.

### Description of the Related Art

In conventional server applications, in order to improve wiring efficiency and facilitate installation operations, the area above the cable connector end is often intentionally kept unobstructed, allowing installation personnel to quickly perform plug-and-unplug operations and thereby accelerate the overall assembly process. However, this approach prevents other mechanisms or components from being arranged in that area, resulting in a waste of spatial resources. On the other hand, if a fixed structure is disposed above the connector, the object above must be removed before cable plugging or unplugging can be performed, which not only introduces additional operational steps but also significantly reduces convenience and efficiency during maintenance and upgrades.

Accordingly, how to develop a server device that provides both installation convenience and efficient space utilization has become a key issue for improving server assembly efficiency and maintenance performance.

### SUMMARY OF THE INVENTION

The invention provides a server device that addresses the problems in the prior art of wasted internal space within the server and inconvenience in installing and removing components.

One embodiment of the invention provides a server device including a casing, a first vertical wall, a second vertical wall, and an expansion module rack. The casing includes a base plate. The first vertical wall and the second vertical wall are fixed to the base plate, and the first vertical wall and the second vertical wall are disposed parallel to and spaced apart from each other to define a receiving bay between the first vertical wall and the second vertical wall. The expansion module rack is detachably inserted into the receiving bay and is slidable to an assembly position or a pre-assembly position. When the expansion module rack is in the assembly position, the expansion module rack at least partially covers a cable routing space located between the expansion module rack and the base plate. When the expansion module rack is moved from the assembly position to pre-assembly position, the expansion module rack exposes the cable routing space.

According to the server device as described above, by detachably inserting the expansion module rack into the receiving bay and allowing the expansion module rack to slide to the assembly position or the pre-assembly position, a two-stage positioning function is provided. This configuration ensures that, during the process of moving the expansion module rack out of the receiving bay, cables connected to the expansion module rack are not damaged due to excessive pulling, thereby enabling full utilization of the space above the cable routing space while also maintaining convenience in cable routing operations.

### BRIEF DESCRIPTION OF THE DRAWINGS

The invention will become more fully understood from the detailed description given hereinbelow and the accompanying drawings which are given by way of illustration only and thus are not limitative of The invention and wherein:

FIG. 1 is a perspective view of a server device in accordance with one embodiment of the invention;

FIG. 2 is a top view of the server device shown in FIG. 1;

FIG. 3 is an exploded view of the server device shown in FIG. 1;

FIG. 4 is another exploded view of the server device shown in FIG. 1;

FIG. 5 is a perspective view of an expansion module rack of the server device shown in FIG. 1;

FIG. 6 is another perspective view of the expansion module rack of the server device shown in FIG. 1;

FIG. 7 is a perspective view showing the expansion module rack of the server device of FIG. 1 located in a pre-assembly position; and

FIG. 8 is an enlarged partial schematic view of region EL8 of FIG. 7.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the invention, such as technical and scientific terms, have its own meanings and can be comprehended by those skilled in the art, unless the terms are additionally defined in the invention. That is, the terms used in the following paragraphs should be read on the meaning commonly used in the related fields and will not be overly explained, unless the terms have a specific meaning in the invention.

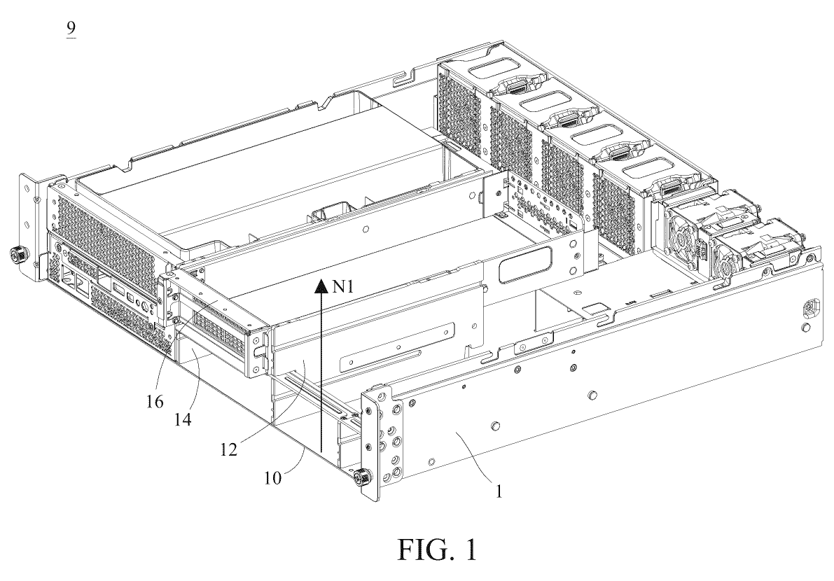

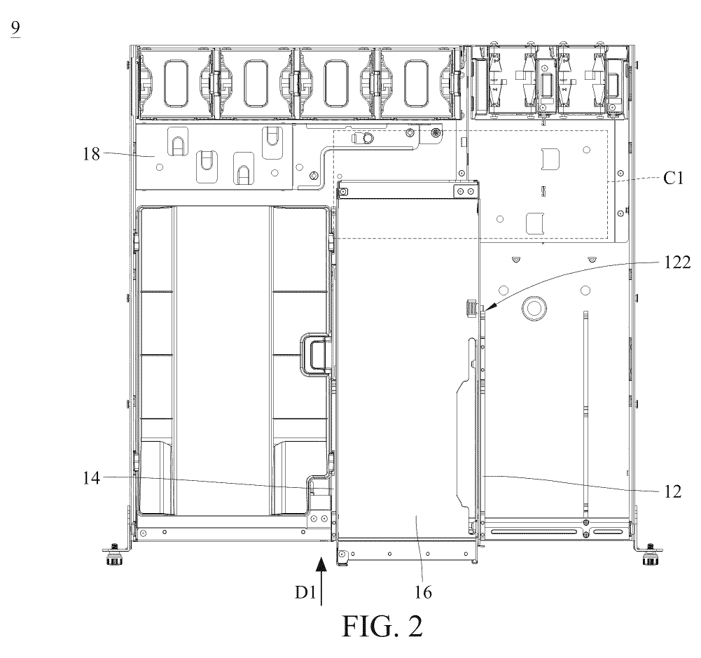

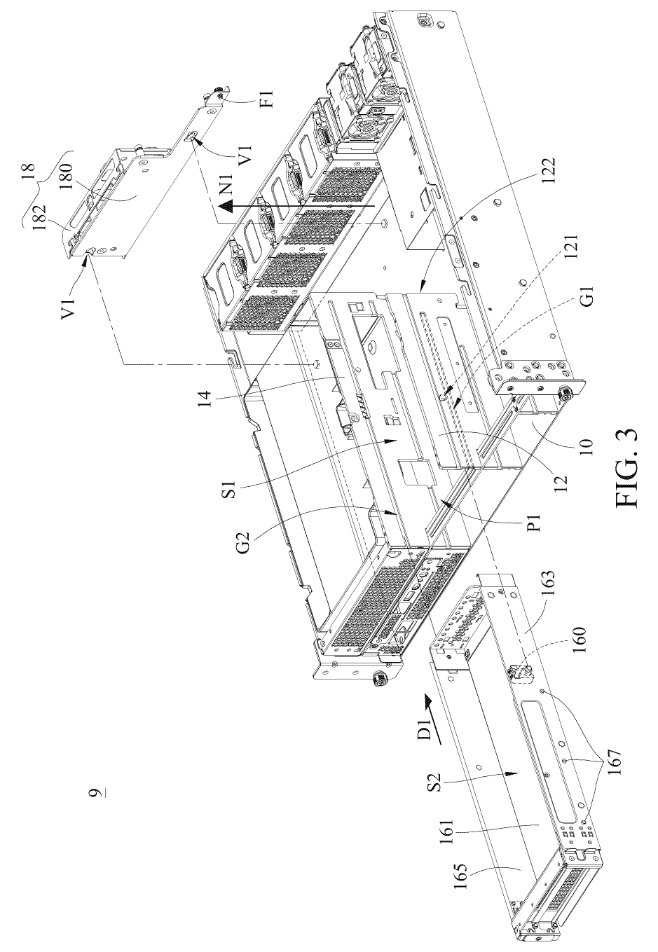

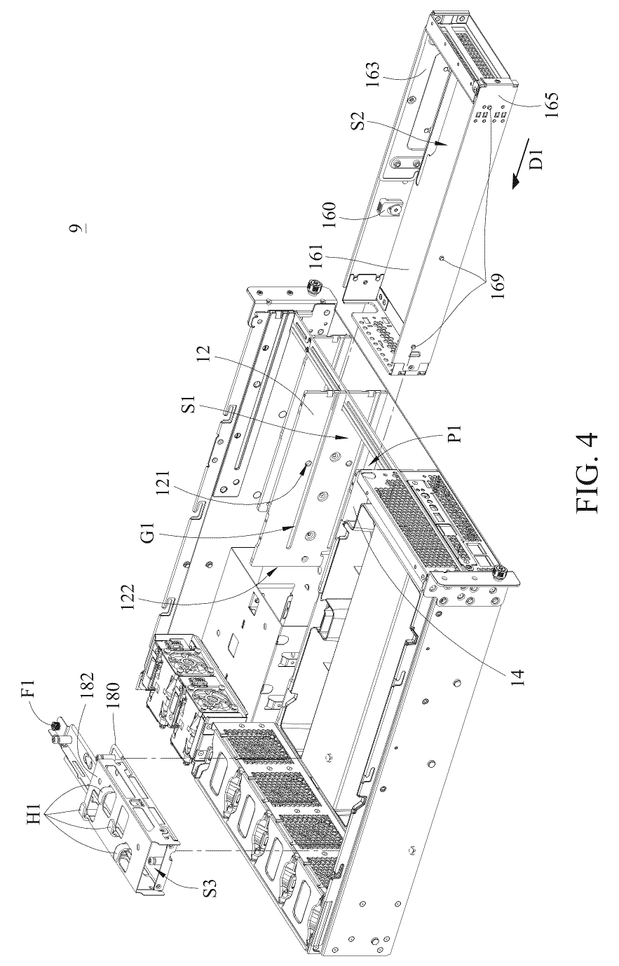

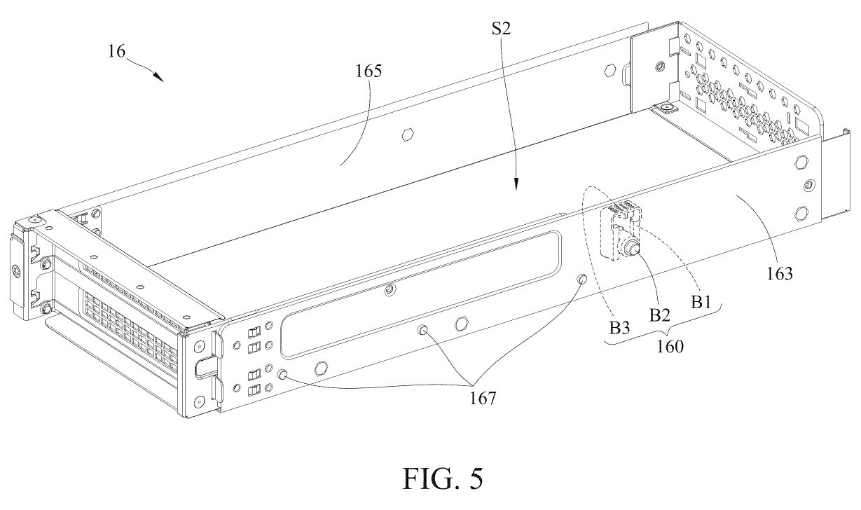

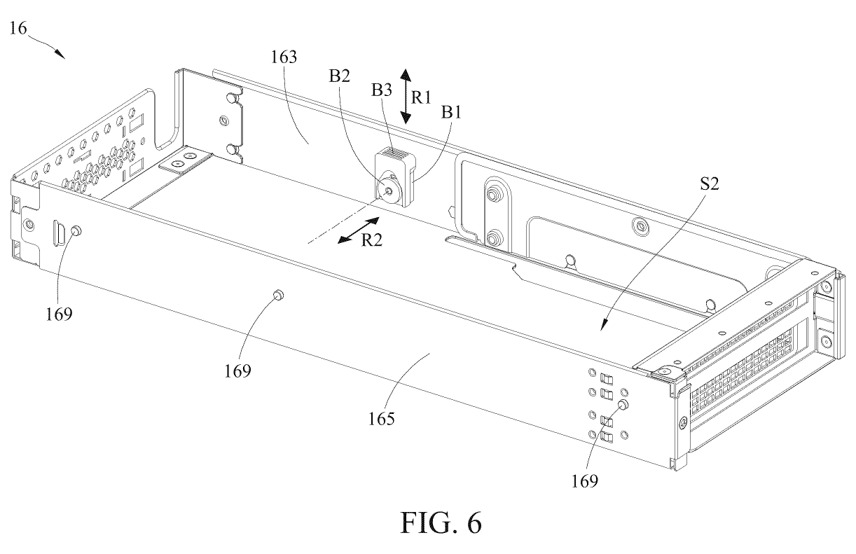

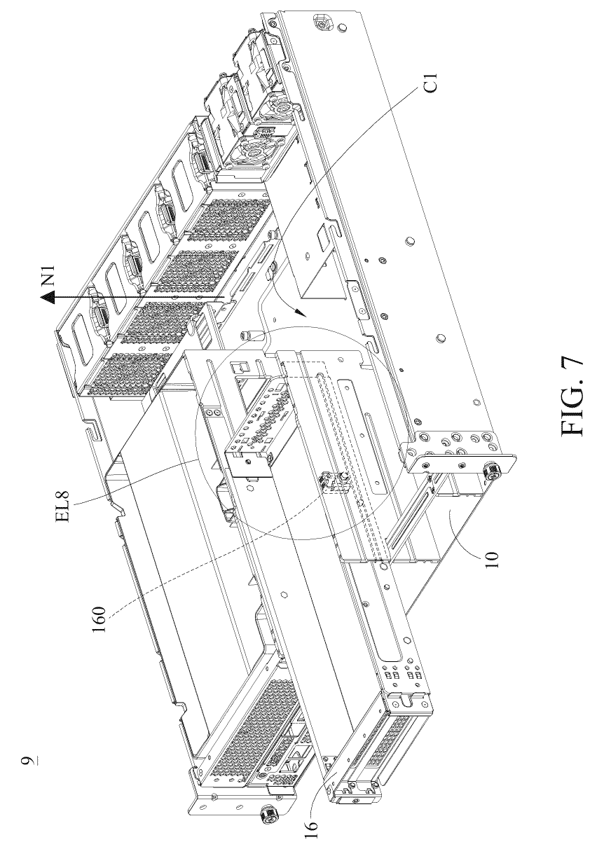

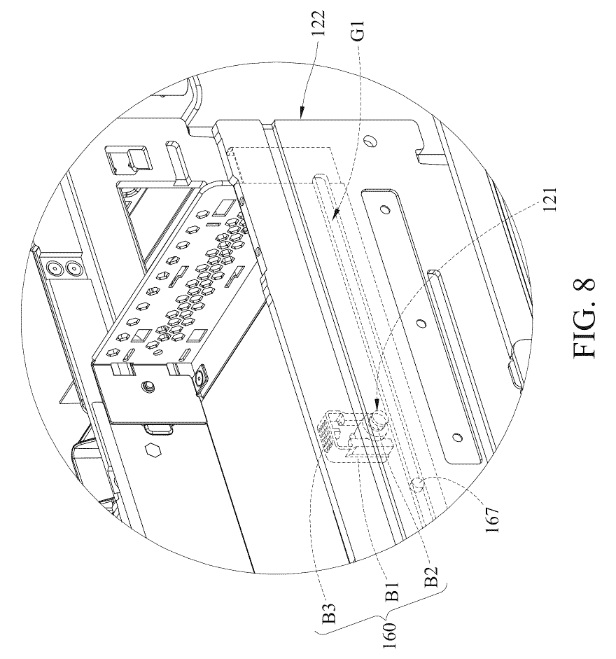

Referring to FIGS. 1-8, FIG. 1 is a perspective view of a server device in accordance with one embodiment of the invention, FIG. 2 is a top view of the server device shown in FIG. 1, FIG. 3 is an exploded view of the server device shown in FIG. 1, FIG. 4 is another exploded view of the server device shown in FIG. 1, FIG. 5 is a perspective view of an expansion module rack of the server device shown in FIG. 1, FIG. 6 is another perspective view of the expansion module rack of the server device shown in FIG. 1, FIG. 7 is a perspective view showing the expansion module rack of the server device of FIG. 1 located in a pre-assembly position, and FIG. 8 is an enlarged partial schematic view of region EL8 of FIG. 7.

In this embodiment, a server device 9 is provided. The server device 9 includes a motherboard (not shown), an expansion card (not shown), a first vertical wall 12, a second vertical wall 14, an expansion module rack 16, and a casing 1. The casing 1 includes a base plate 10. The expansion card may be, for example, a graphics card, but the invention is not limited thereto.

The motherboard is disposed on the base plate 10, and the expansion card is mounted on the expansion module rack 16. The first vertical wall 12 and the second vertical wall 14 are vertically fixed to the base plate 10, and the first vertical wall 12 and the second vertical wall 14 are disposed parallel to and spaced apart from each other so as to define a receiving bay S1 between the first vertical wall 12 and the second vertical wall 14. The expansion module rack 16 is detachably inserted into the receiving bay S1 and is slidable to an assembly position (as shown in FIGS. 1 and 2) or a pre-assembly position (as shown in FIG. 7).

As shown in FIGS. 1 and 2, when the expansion module rack 16 is in the assembly position, the expansion module rack 16 at least partially covers a cable routing space C1 located between the expansion module rack 16 and the base plate 10, thereby fully utilizing the space above the cable routing space C1. As shown in FIG. 7, when the expansion module rack 16 is moved from the assembly position to the pre-assembly position, the expansion module rack 16 exposes the cable routing space C1, facilitating cable routing operations.

The first vertical wall 12 includes a first positioning structure 121 and a second positioning structure 122, and the second positioning structure 122 is located farther from an opening P1 of the receiving bay S1 than the first positioning structure 121. The expansion module rack 16 is detachably inserted into the receiving bay S1 through the opening P1, and the expansion module rack 16 includes a latch component 160. During insertion of the expansion module rack 16, the latch component 160 can detachably engage the first positioning structure 121 (corresponding to the pre-assembly position) or the second positioning structure 122 (corresponding to the assembly position). Accordingly, a two-stage positioning function is provided to ensure that, during the process of moving the expansion module rack 16 out of the receiving bay S1, cables connected to the expansion module rack 16 are not damaged due to excessive pulling, while also facilitating sliding operation of the expansion module rack 16 and cable management or plugging/unplugging within the cable routing space C1. The latch component 160 may be, for example, an automatically engaging fastener.

Specifically, as shown in FIGS. 7 and 8, when the expansion module rack 16 is in the pre-assembly position, the latch component 160 detachably engages the first positioning structure 121, and the expansion module rack 16 does not overlap the cable routing space C1 in a normal direction N1 of the base plate 10; that is, the expansion module rack 16 exposes the cable routing space C1. As shown in FIGS. 1 and 2, when the expansion module rack 16 is in the assembly position, the latch component 160 detachably engages the second positioning structure 122, and the expansion module rack 16 at least partially overlaps the cable routing space C1 in the normal direction N1 of the base plate 10; that is, the expansion module rack 16 at least partially covers the cable routing space C1.

As shown in FIGS. 3-6, the first vertical wall 12 further includes a first slide rail G1, the second vertical wall 14 includes a second slide rail G2, and the first slide rail G1 and the second slide rail G2 are both parallel to a module insertion direction D1 of the receiving bay S1. The expansion module rack 16 further includes a carrier plate 161, a first side plate 163, a second side plate 165, a plurality of first sliding blocks 167, and a plurality of second sliding blocks 169. The first side plate 163 and the second side plate 165 are respectively connected to opposite sides of the carrier plate 161 and together define an expansion card accommodating space S2 for receiving the expansion card. In addition, the latch component 160 is disposed on the first side plate 163.

The first sliding blocks 167 are disposed on a side of the first side plate 163 facing away from the second side plate 165 and are arranged in a direction parallel to the module insertion direction D1. The second sliding blocks 169 are disposed on a side of the second side plate 165 facing away from the first side plate 163 and are arranged in a direction parallel to the module insertion direction D1. The first sliding blocks 167 are slidably disposed in the first slide rail G1, and the second sliding blocks 169 are slidably disposed in the second slide rail G2, thereby providing a guiding function for sliding movement.

As shown in FIGS. 3 and 4, the first positioning structure 121 is a positioning hole, and the second positioning structure 122 is a stop end surface. The stop end surface is located at an end portion of the first vertical wall 12 that is farther from the opening P1, but the invention is not limited thereto.

As shown in FIGS. 5 and 6, the latch component 160 includes a fixing base B1, a latch pin B2, an operation portion B3, and a restoring component (not shown). The fixing base B1 is fixed to the first side plate 163. The latch pin B2 is movably disposed on the fixing base B1 and is extendable and retractable so as to protrude from the side of the first side plate 163 facing away from the second side plate 165. The operation portion B3 is movably disposed on the fixing base B1, and the operation portion B3 is connected to the latch pin B2 and is configured to receive an external force to drive the latch pin B2 to move to an insertion position or a withdrawal position. The restoring component is connected to and located between the latch pin B2 and the fixing base B1, and is configured to apply a force to the latch pin B2 to push the latch pin B2 back to the insertion position. However, the invention is not limited to the foregoing configuration of the latch component 160.

As shown in FIGS. 7 and 8, when the expansion module rack 16 is in the pre-assembly position, the latch pin B2 is pushed by the restoring component to the insertion position and is detachably inserted into the first positioning structure 121, thereby positioning the expansion module rack 16 in the pre-assembly position; when the operation portion B3 is subjected to an external force to drive the latch pin B2 to move from the insertion position to the withdrawal position and disengage from the first positioning structure 121, the expansion module rack 16 is moved from the pre-assembly position toward the opening P1 or toward the assembly position.

As shown in FIGS. 1 and 2, when the expansion module rack 16 is in the assembly position, the latch pin B2 is pushed by the restoring component to the insertion position and detachably abuts the second positioning structure 122, thereby positioning the expansion module rack 16 in the assembly position; when the operation portion B3 is subjected to an external force to drive the latch pin B2 to move from the insertion position to the withdrawal position and disengage from the second positioning structure 122, the expansion module rack 16 is moved from the assembly position toward the pre-assembly position, thereby facilitating cable routing and subsequent removal or adjustment of the expansion module rack 16.

Further, the operation portion B3 includes an inclined pushing surface (not separately labeled), the latch pin B2 includes a tapered surface (not separately labeled), and the inclined pushing surface is in slidable physical contact with the tapered surface. When the operation portion B3 is actuated by an external force to push the latch pin B2, the inclined pushing surface drives the tapered surface to undergo relative sliding, allowing the latch pin B2 to move from the insertion position to the withdrawal position and thereby achieving a quick-release function. However, the invention is not limited to the foregoing configurations of the operation portion B3 and the latch pin B2. On the other hand, when the operation portion B3 is not subjected to a force directed toward the latch pin B2, the latch pin B2 is pushed by the restoring component to move to the insertion position. A moving direction R1 of the operation portion B3 is perpendicular to an extending and retracting direction R2 of the latch pin B2, thereby facilitating force transmission and operational space design, but the invention is not limited thereto.

In this embodiment, the restoring component is, for example, a spring, thereby providing a stable restoring force; however, the invention is not limited thereto.

In this embodiment, a quantity of the first sliding blocks 167 is three, and a quantity of the second sliding blocks 169 is also three, thereby enhancing guiding stability; however, the invention is not limited thereto.

In this embodiment, a distance between the first positioning structure 121 and the opening P1 is less than a distance between the first positioning structure 121 and the second positioning structure 122, thereby providing a wider cable routing space C1; however, the invention is not limited thereto.

As shown in FIGS. 3 and 4, the server device 9 further includes a memory card module rack 18 (e.g., an M.2 module rack), and the memory card module rack 18 is fixed to the base plate 10 and has modular and quick-release characteristics. The memory card module rack 18 may be a metal housing (such as a steel casing), thereby providing good structural strength, heat dissipation performance, and/or shielding effectiveness, and facilitating assembly and disassembly.

The memory card module rack 18 includes a base 180 and a cover 182, and the base 180 and the cover 182 cooperate to form a module accommodating space S3. The cover 182 includes a plurality of cable routing structures H1, and the cable routing structures H1 may be, for example, hook-shaped structures configured to accommodate different cable arrangement requirements and guide cables toward relatively open areas to prevent congested regions, thereby achieving cable distribution and optimized cable routing effects.

The base 180 includes two keyhole slots V1 and a thumb screw F1. The memory card module rack 18 is quickly positioned via the keyhole slots V1 and fixed to the base plate 10 using the thumb screw F1, thereby facilitating rapid installation or removal of the module assembly. This quick-release design allows a user to remove the memory card module rack 18 without additional tools when the motherboard requires repair or replacement, enabling the motherboard to be removed together with the memory card module rack 18 and thereby improving modular maintenance convenience and operational efficiency.

In this embodiment, the server device of the invention can be used for artificial intelligence (AI) computing, edge computing, and can also be used as a 5G server, a cloud server, or a server for vehicle-to-everything.

According to the server device as described above, by detachably inserting the expansion module rack into the receiving bay and allowing the expansion module rack to slide to the assembly position or the pre-assembly position, a two-stage positioning function is provided. This configuration ensures that, during the process of moving the expansion module rack out of the receiving bay, cables connected to the expansion module rack are not damaged due to excessive pulling, thereby enabling full utilization of the space above the cable routing space while also maintaining convenience in cable routing operations.

It will be apparent to those skilled in the art that various modifications and variations can be made to the invention. It is intended that the specification and examples be considered as exemplary embodiments only, with a scope of the invention being indicated by the following claims and their equivalents.

What is claimed is:

1. A server device comprising:
a casing comprising a base plate;
a first vertical wall fixed to the base plate;
a second vertical wall fixed to the base plate, wherein the first vertical wall and the second vertical wall are disposed parallel to and spaced apart from each other so as to define a receiving bay between the first vertical wall and the second vertical wall; and
an expansion module rack detachably inserted into the receiving bay and slidable to an assembly position or a pre-assembly position;
wherein, when the expansion module rack is in the assembly position, the expansion module rack at least partially covers a cable routing space located between the expansion module rack and the base plate; and
wherein, when the expansion module rack is moved from the assembly position to the pre-assembly position, the expansion module rack exposes the cable routing space.

2. The server device according to claim 1, wherein the first vertical wall comprises a first positioning structure and a second positioning structure, the second positioning structure is located farther from an opening of the receiving bay than the first positioning structure, the expansion module rack is detachably inserted into the receiving bay through the opening, and the expansion module rack comprises a latch component;
wherein, when the expansion module rack is in the pre-assembly position, the latch component detachably engages the first positioning structure, and the expansion module rack does not overlap the cable routing space in a normal direction of the base plate; and
wherein, when the expansion module rack is in the assembly position, the latch component detachably engages the second positioning structure, and the expansion module rack at least partially overlaps the cable routing space in the normal direction of the base plate.

3. The server device according to claim 2, wherein the first vertical wall further comprises a first slide rail, the second vertical wall comprises a second slide rail, the first slide rail and the second slide rail are both parallel to a module insertion direction of the receiving bay, the expansion module rack further comprises a carrier plate, a first side plate, a second side plate, a plurality of first sliding blocks, and a plurality of second sliding blocks, the first side plate and the second side plate are respectively connected to opposite sides of the carrier plate and together define an expansion card accommodating space, the latch component is disposed on the first side plate, the plurality of first sliding blocks are disposed on a side of the first side plate facing away from the second side plate and are arranged in a direction parallel to the module insertion direction, the plurality of second sliding blocks are disposed on a side of the second side plate facing away from the first side plate and are arranged in a direction parallel to the module insertion direction, the plurality of first sliding blocks are slidably disposed in the first slide rail, and the plurality of second sliding blocks are slidably disposed in the second slide rail.

4. The server device according to claim 3, wherein the first positioning structure is a positioning hole, the second positioning structure is a stop end surface, the stop end surface is located at an end portion of the first vertical wall that is farther from the opening, the latch component comprises a fixing base, a latch pin, an operation portion, and a restoring component, the fixing base is fixed to the first side plate, the latch pin is movably disposed on the fixing base and is extendable and retractable so as to protrude from the side of the first side plate facing away from the second side plate, the operation portion is movably disposed on the fixing base, the operation portion is connected to the latch pin and is configured to receive an external force to drive the latch pin to move to an insertion position or a withdrawal position, and the restoring component is connected to and located between the latch pin and the fixing base and is configured to apply a force to the latch pin to push the latch pin toward the insertion position;
wherein, when the expansion module rack is in the pre-assembly position, the latch pin is pushed by the restoring component to the insertion position and is detachably inserted into the first positioning structure, thereby positioning the expansion module rack in the pre-assembly position, and the operation portion is subjected to an external force to drive the latch pin to move from the insertion position to the withdrawal position and disengage from the first positioning structure, allowing the expansion module rack to move from the pre-assembly position toward the opening or toward the assembly position;
wherein, when the expansion module rack is in the assembly position, the latch pin is pushed by the restoring component to the insertion position and detachably abuts the second positioning structure, thereby positioning the expansion module rack in the assembly position, and the operation portion is subjected to an external force to drive the latch pin to move from the insertion position to the withdrawal position and disengage from the second positioning structure, allowing the expansion module rack to move from the assembly position toward the pre-assembly position.

5. The server device according to claim 4, wherein a moving direction of the operation portion is perpendicular to an extending and retracting direction of the latch pin.

6. The server device according to claim 4, wherein the restoring component is a spring.

7. The server device according to claim 3, wherein a quantity of the plurality of first sliding blocks is at least three, and a quantity of the plurality of second sliding blocks is at least three.

8. The server device according to claim 2, wherein a distance between the first positioning structure and the opening is less than a distance between the first positioning structure and the second positioning structure.
